(19) United States
(12) Patent Application Publication
(10) Pub. No.: US 2025/0210608 A1
(43) Pub. Date: Jun. 26, 2025

(54) INTEGRATED CIRCUIT PACKAGES WITH THERMAL RESERVOIR DIES AND METHODS OF FORMING THE SAME

(71) Applicant: Taiwan Semiconductor Manufacturing Co., Ltd., Hsinchu (TW)

(72) Inventors: Lipu Kris Chuang, Hsinchu (TW); Yi-Hsuan Wu, Miaoli County (TW); Chihting Lai, Hsinchu (TW); Hsin Ting Lin, Hsinchu County (TW); Tsung-Yu Chen, Hsinchu (TW)

(21) Appl. No.: 18/600,172

(22) Filed: Mar. 8, 2024

Related U.S. Application Data
(60) Provisional application No. 63/614,700, filed on Dec. 26, 2023.

(51) Int. Cl. H01L 25/18; H01L 21/48; H01L 23/00; H01L 23/373; H01L 23/433; H01L 23/498; H01L 23/538; H01L 25/00; H10B 80/00

(52) U.S. Cl. CPC H01L 25/18; H01L 21/4846; H01L 23/3736; H01L 23/3738; H01L 23/4334; H01L 23/49833; H01L 23/5385; H01L 24/19; H01L 24/20; H01L 25/50; H10B 80/00; H01L 24/13; H01L 24/16; H01L 24/29; H01L 24/32; H01L 24/73; H01L 24/81; H01L 24/83; H01L 24/92; H01L 2224/13111; H01L 2224/13124; H01L 2224/13139; H01L 2224/13144; H01L 2224/13147; H01L 2224/13155; H01L 2224/13164; H01L 2224/16227; H01L 2224/19; H01L 2224/211; H01L 2224/2919; H01L 2224/32225; H01L 2224/73204; H01L 2224/81815; H01L 2224/83102; H01L 2224/92125; H01L 2924/0665; H01L 2924/1431; H01L 2924/1436; H01L 2924/1437

(57) ABSTRACT

In an embodiment, a device includes: an interposer including: a front-side redistribution structure; a back-side redistribution structure; an encapsulant between the front-side redistribution structure and the back-side redistribution structure; an interconnection die in the encapsulant; and a thermal reservoir die in the encapsulant, the thermal reservoir die adjacent the interconnection die; a memory device attached to the front-side redistribution structure, the memory device overlapping the thermal reservoir die in a plan view; and a logic device attached to the front-side redistribution structure, the logic device and the memory device each overlapping the interconnection die in the plan view.

### PRIORITY CLAIM AND CROSS-REFERENCE

This application claims the benefit of U.S. Provisional Application No. 63/614,700, filed on Dec. 26, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2A-2B are cross-sectional views of die stacks.

FIGS. 3-12 are views of intermediate stages in the manufacturing of an integrated circuit package, in accordance with some embodiments.

FIGS. 13-14B are views of an integrated circuit package, in accordance with some other embodiments.

FIG. 15 is a cross-sectional view of an integrated circuit package, in accordance with some other embodiments.

FIG. 16 is a cross-sectional view of an integrated circuit package, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, an interposer of an integrated circuit package includes a molding compound between two redistribution structures. Interconnection dies and thermal reservoir dies are disposed in the molding compound, and thus are embedded in the interposer. The interconnection dies may include active devices, which may cause the interconnection dies to consume a high amount of power and generate a large amount of heat during operation. The thermal reservoir dies are electrically nonfunctional, and act as heat sinks for the interconnection dies with active devices. During operation, heat may be dissipated from the interconnection dies to the thermal reservoir dies. The operating temperature of the interconnection dies may thus be decreased, which may improve the performance of the integrated circuit package.

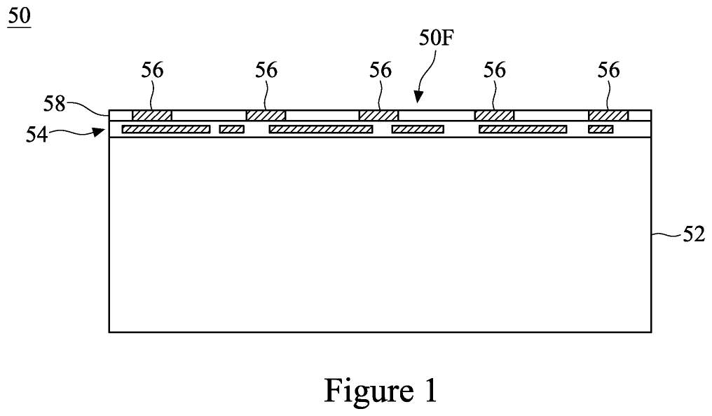

FIG. 1 is a cross-sectional view of an integrated circuit die 50. Multiple integrated circuit dies 50 will be packaged in subsequent processing to form integrated circuit packages. Each integrated circuit die 50 may be a logic die (e.g., central processing unit (CPU), graphics processing unit (GPU), system-on-a-chip (SoC) die, microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) are at the active surface of the semiconductor substrate 52. The devices may be active devices (e.g., transistors, diodes, etc.), capacitors, resistors, etc. The inactive surface may be free from devices.

The interconnect structure 54 is over the active surface of the semiconductor substrate 52, and is used to electrically connect the devices of the semiconductor substrate 52 together to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide, nitrides such as silicon nitride, combinations thereof such as silicon oxynitride, or the like. Other dielectric materials may also be used, such as a polymer, such as polybenzoxazole (PBO), polyimide, a benzocyclobuten (BCB) based polymer, or the like. The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Die connectors 56 are at the front-side 50F of the integrated circuit die 50. The die connectors 56 may be conductive pillars, pads, or the like, to which external connections are made. The die connectors 56 are in and/or on the interconnect structure 54. For example, the die connectors 56 may be part of an upper metallization layer of the interconnect structure 54. The die connectors 56 may be formed of a metal, such as copper, aluminum, or the like, and may be formed by, for example, plating, or the like.

Optionally, solder regions (not separately illustrated) may be disposed on the die connectors 56 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 56. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed.

A dielectric layer 58 is at the front-side 50F of the integrated circuit die 50. The dielectric layer 58 is in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a polymer, the like, or a combination thereof, which may be formed, for example, by spin coating, lamination, chemical vapor deposition (CVD), or the like. Front-side surfaces of the die connectors 56 and the dielectric layer 58 may be substantially coplanar (within process variations) at the front-side 50F of the integrated circuit die 50.

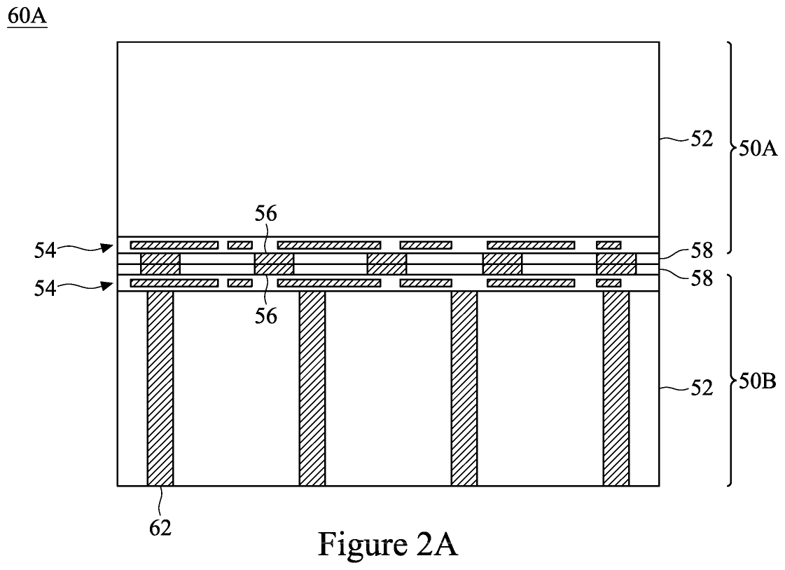

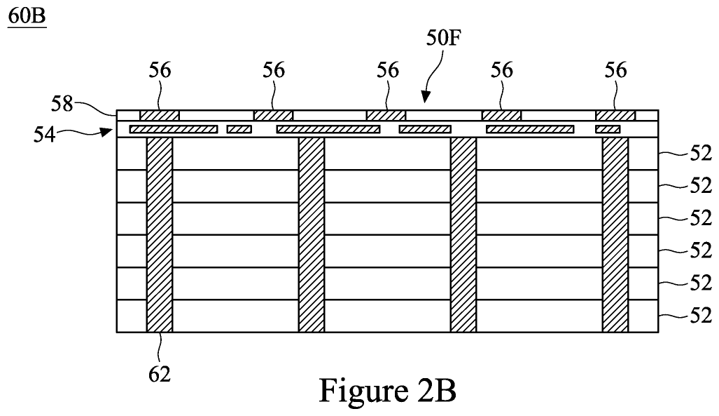

FIGS. 2A-2B are cross-sectional views of die stacks 60A, 60B, respectively. The die stacks 60A, 60B may each have a single function (e.g., a logic device, memory die, etc.), or may have multiple functions. In some embodiments, the die stack 60A is a logic device such as a system-on-integrated-chip (SoIC) device and the die stack 60B is a memory device such as high bandwidth memory (HBM) device.

As shown in FIG. 2A, the die stack 60A includes two bonded integrated circuit dies 50 (e.g., a first integrated circuit die 50A and a second integrated circuit die 50B). In some embodiments, the first integrated circuit die 50A is a logic die, and the second integrated circuit die 50B is an interface die. An interface die bridges a logic die to memory dies, and translates commands between the logic die and the memory dies. In some embodiments, the first integrated circuit die 50A and the second integrated circuit die 50B are bonded such that the active surfaces are facing each other (e.g., are “face-to-face” bonded). Conductive vias 62 may be formed through one of the integrated circuit dies 50 so that external connections may be made to the die stack 60A. The conductive vias 62 may be through-substrate vias (TSVs), such as through-silicon vias or the like. In the illustrated embodiment, the conductive vias 62 are formed in the second integrated circuit die 50B (e.g., the interface die). The conductive vias 62 extend through the semiconductor substrate 52 of the respective integrated circuit die 50, to be physically and electrically connected to the metallization layer(s) of the interconnect structure 54.

As shown in FIG. 2B, the die stack 60B is a stacked device that includes multiple semiconductor substrates 52. For example, the die stack 60B may be a memory device that includes multiple memory dies such as a hybrid memory cube (HMC) device, a high bandwidth memory (HBM) device, or the like. Each semiconductor substrate 52 may (or may not) have a separate interconnect structure 54. The semiconductor substrates 52 are connected by conductive vias 62, such as TSVs.

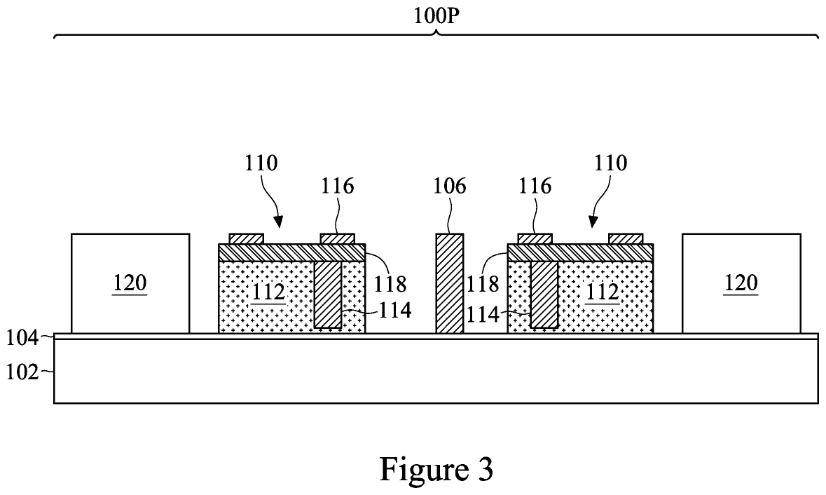

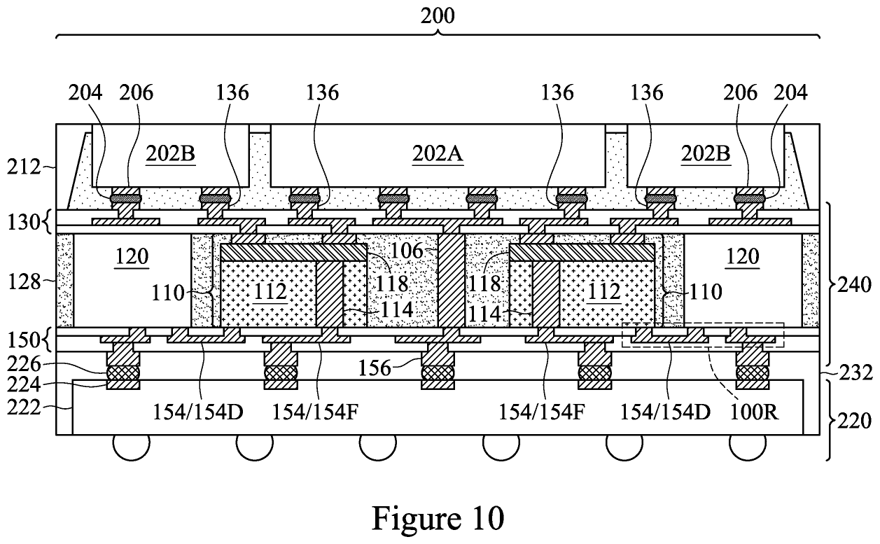

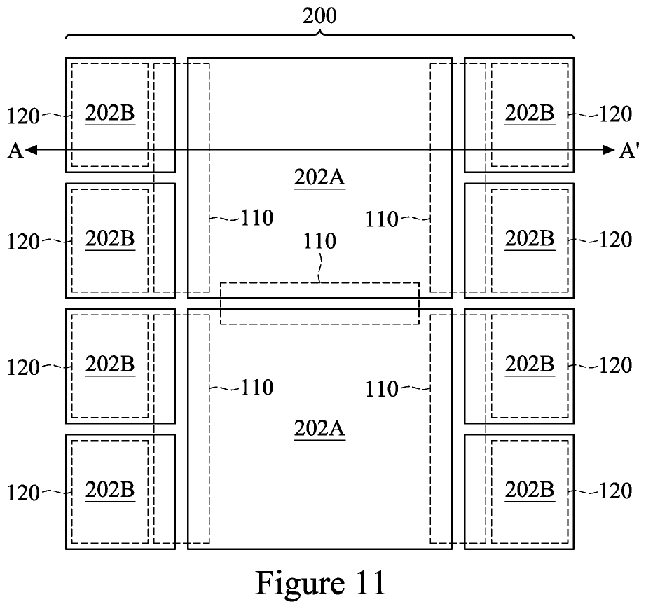

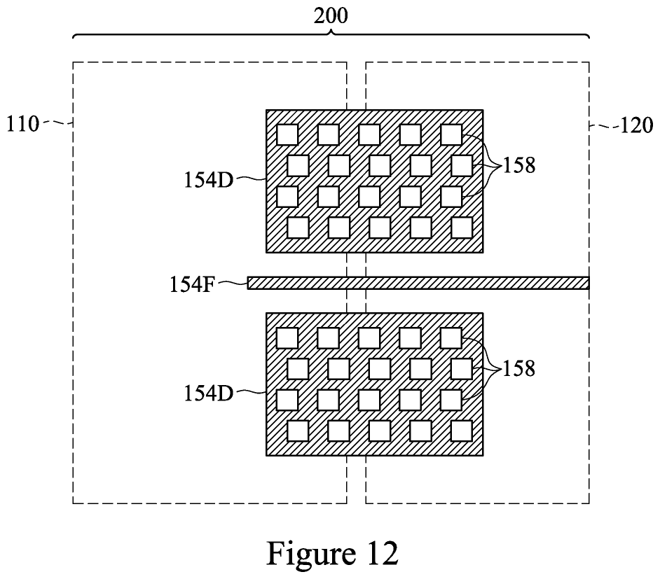

FIGS. 3-12 are views of intermediate stages in the manufacturing of an integrated circuit package 200 (see FIGS. 10-12), in accordance with some embodiments. FIGS. 3-10 are cross-sectional views while FIGS. 11-12 are plan views (or top-down views). A package region 100P is illustrated, and an integrated circuit package 200 is formed in the package region 100P. Although a single package region 100P is illustrated, it should be appreciated that multiple package regions 100P may be formed. An interposer wafer 100 is formed. The interposer wafer 100 includes an interposer 240 in the package region 100P. Integrated circuit devices 202 are attached to the interposer 240. The interposer 240 may include interconnection dies 110 for interconnecting the integrated circuit devices 202 in the package region 100P. A package substrate 220 is attached to the interposer 240. The package region 100P is singulated to form the integrated circuit package 200, which includes the package substrate 220 and a singulated portion of the interposer wafer 100 (e.g., the interposer 240). In an embodiment, the integrated circuit package 200 is a chip-on-wafer-on-substrate (CoWoS®) package, such as a CoWoS-L package, although it should be appreciated that embodiments may be applied to other three-dimensional integrated circuit (3DIC) packages.

In FIG. 3, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

Through vias 106 are formed over the release layer 104. Although the illustrated cross-section shows a single through via 106, it should be appreciated that multiple through vias 106 may be formed. As an example to form the through vias 106, a seed layer (not separately illustrated) is formed over the release layer 104. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as physical vapor deposition (PVD) or the like. A photoresist is then formed and patterned on the seed layer. The photoresist may be formed by spin coating or the like and may be exposed to light for patterning. The pattern of the photoresist corresponds to the through vias 106. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the through vias 106.

Interconnection dies 110 are placed on the release layer 104. The interconnection dies 110 may be placed on the release layer 104 using, e.g., a pick-and-place tool. The interconnection dies 110 will be utilized for direct communication between integrated circuit devices (subsequently described) of the integrated circuit package 200.

Each interconnection die 110 may be a local silicon interconnect (LSI), a large scale integration package, an interposer die, or the like. The interconnection dies 110 may be bridge dies. In the illustrated cross-section, two interconnection dies 110 are attached in the package region 100P. It should be appreciated that any desired quantity of interconnection dies 110 may be attached in each package region 100P.

Each interconnection die 110 includes a substrate 112, with conductive features formed in and/or on the substrate 112. The substrates 112 may include a semiconductor substrate, one or more dielectric layer(s), or the like. Additionally, each interconnection die 110 may include through-substrate vias (TSVs) 114 that extend into or through the substrate 112, and may be coupled to the conductive features of the interconnection die 110. In the illustrated embodiment, the substrates 112 initially cover the TSVs 114 at the back-sides of the interconnection dies 110. In another embodiment, the TSVs 114 are exposed at the back-sides of the interconnection dies 110. The interconnection die 110 also includes die connectors 116 disposed at the front-side of the interconnection die 110. Some of the die connectors 116 may be electrically coupled to the back-side of the interconnection die 110 by the TSVs 114. The TSVs 114 may be small, such as smaller than the through vias 106.

In some embodiments, the interconnection dies 110 may include die bridges 118. The die bridges 118 may be metallization layers formed in and/or on, e.g., the substrates 112, and work to interconnect integrated circuit devices (subsequently described) to one another. The die bridges 118 may include interconnects, redistribution lines, or the like. The die bridges 118 are located at the front-side of the interconnection dies 110. As such, the interconnection dies 110 can be used to directly connect and allow communication between integrated circuit devices. In such embodiments, the interconnection dies 110 may be placed in respective regions that are disposed between the subsequently attached integrated circuit devices, so that each interconnection die 110 is overlapped by multiple overlying integrated circuit devices. In some embodiments, the interconnection dies 110 may further include passive devices and/or active devices. In some embodiments, the interconnection dies 110 are substantially free of active devices and passive devices. The interconnection dies 110 may be placed over the carrier substrate 102 such that the die bridges 118 face away from the carrier substrate 102 (e.g., towards the subsequently attached integrated circuit devices).

Thermal reservoir dies 120 are placed on the release layer 104. The thermal reservoir dies 120 may be placed on the release layer 104 using, e.g., a pick-and-place tool. The thermal reservoir dies 120 are placed adjacent to respective interconnection dies 110. Some types of interconnection dies 110, such as those with active devices, may consume a high amount of power and generate a large amount of heat during operation. The thermal reservoir dies 120 will be utilized as heat sinks to draw heat away from the interconnection dies 110 during operation.

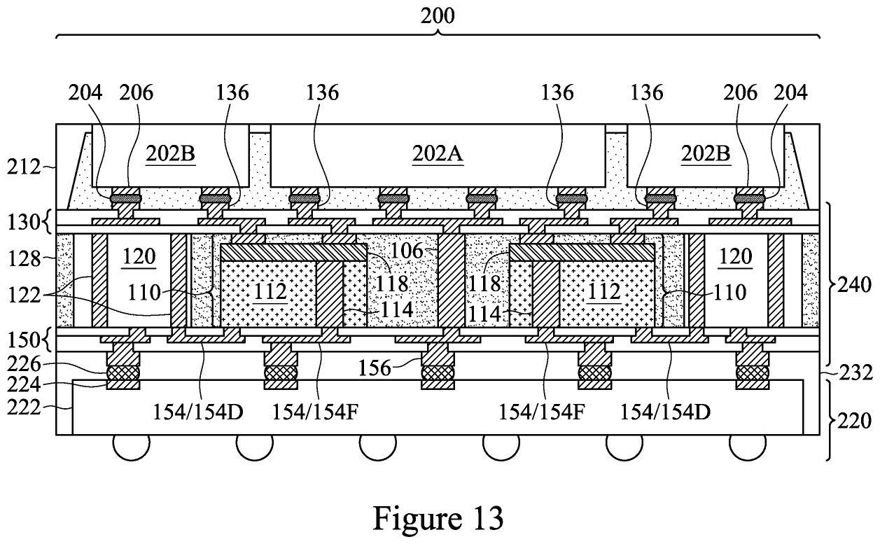

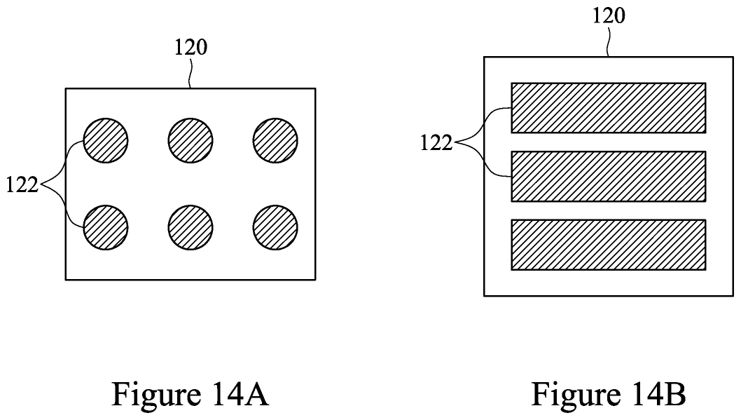

Each thermal reservoir die 120 includes a substrate, which may include a single, continuous layer of a material. In some embodiments, the thermal reservoir dies 120 include semiconductor substrates. The semiconductor substrates may be formed of a semiconductor material such as silicon. The semiconductor substrates may be formed by a suitable growth process. In some embodiments, the thermal reservoir dies 120 include metal substrates. The metal substrates may be formed of a metal such as copper. The metal substrates may be formed by a suitable machining process. In some embodiments (subsequently described for FIGS. 13-14B), the thermal reservoir dies 120 include metal features in the substrates.

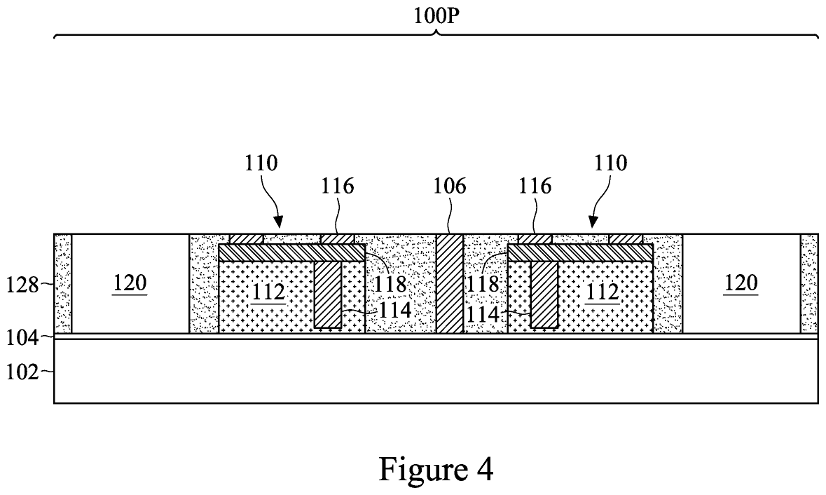

In FIG. 4, an encapsulant 128 is formed around the various components. After formation, the encapsulant 128 laterally encapsulates the thermal reservoir dies 120, the interconnection dies 110, and the through vias 106. The encapsulant 128 may be a molding compound, epoxy, or the like. The encapsulant 128 may be applied by compression molding, transfer molding, or the like, and may be formed over the carrier substrate 102 such that the thermal reservoir dies 120, the interconnection dies 110, and/or the through vias 106 are buried or covered. The encapsulant 128 may be formed in gap regions between the various components. The encapsulant 128 may be applied in liquid or semi-liquid form and then subsequently cured.

A removal process may optionally be performed on the encapsulant 128 to expose the thermal reservoir dies 120, the interconnection dies 110, and the through vias 106. The removal process may remove material of the encapsulant 128, the thermal reservoir dies 120, the interconnection dies 110, and/or the through vias 106 until the die connectors 116 and the through vias 106 are exposed. The removal process may include, for example, a planarization process such as a chemical-mechanical polish (CMP), a grinding process, or the like. The front-side surfaces of the encapsulant 128, the thermal reservoir dies 120, the interconnection dies 110 (e.g., the die connectors 116), and the through vias 106 may be substantially coplanar (within process variations) after the planarization process. The planarization may be omitted, for example, if the through vias 106 and the die connectors 116 are already exposed. After the removal process, the through vias 106 extend through the encapsulant 128. As such, the through vias 106 may be referred to as through-mold vias (TMVs).

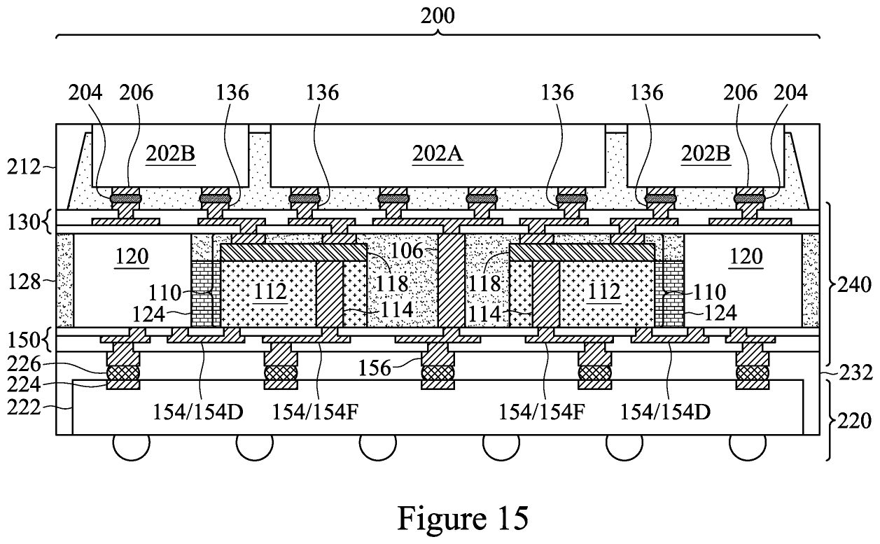

In some embodiments, the encapsulant 128 is formed of a molding material having a high thermal conductivity. Thus, the encapsulant 128 may help dissipate heat from the interconnection dies 110 to the thermal reservoir dies 120 during operation. In some embodiments (subsequently described for FIG. 15), a separate thermal interface material having a high thermal conductivity may be formed between adjacent ones of the thermal reservoir dies 120 and the interconnection dies 110. When the molding material of the encapsulant 128 has a high thermal conductivity, a separate thermal interface material between the adjacent ones of the thermal reservoir dies 120 and the interconnection dies 110 may be omitted.

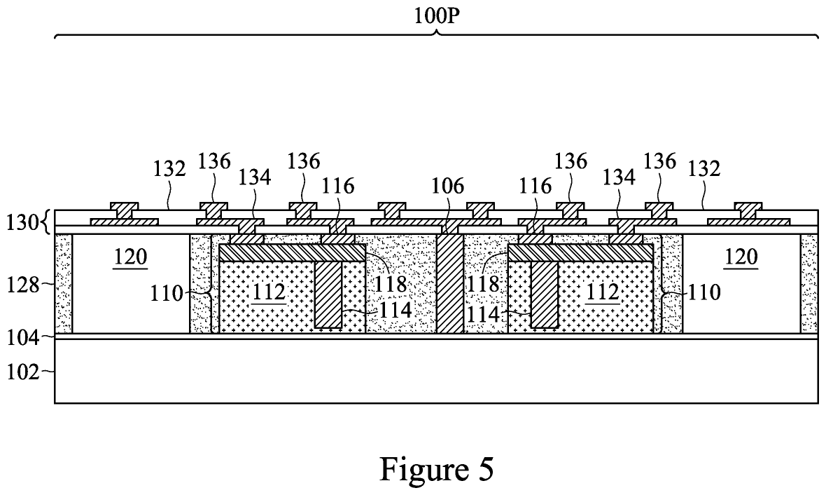

In FIG. 5, a front-side redistribution structure 130 is formed on the front-side surfaces of the encapsulant 128, the thermal reservoir dies 120, the interconnection dies 110 (e.g., the die connectors 116), and the through vias 106. The front-side redistribution structure 130 includes dielectric layers 132 and metallization layer(s) 134 (sometimes referred to as redistribution layers or redistribution lines) among the dielectric layers 132. Thus, the front-side redistribution structure 130 includes metallization layer(s) 134 separated from each other by respective dielectric layers 132. The metallization layer(s) 134 of the front-side redistribution structure 130 are connected to the through vias 106 and to the interconnection dies 110 (e.g., the die connectors 116).

In some embodiments, the dielectric layers 132 are formed of a polymer, which may be a photosensitive material such as PBO, polyimide, a BCB-based polymer, or the like, that may be patterned using a lithography mask. In other embodiments, the dielectric layers 132 are formed of a nitride such as silicon nitride, an oxide such as silicon oxide, or the like. The dielectric layers 132 may be formed by spin coating, lamination, CVD, the like, or a combination thereof. After a dielectric layer 132 is formed, it may be patterned to expose underlying conductive features, such as portions of the through vias 106, the die connectors 116, and/or the metallization layer(s) 134. The patterning may be by any acceptable process, such as by exposing the dielectric layers 132 to light when they are formed of photosensitive material, or by etching using, for example, an anisotropic etch. If the dielectric layers 132 are formed of a photosensitive material, the dielectric layers 132 may be developed after the exposure.

The metallization layer(s) 134 each include conductive vias and/or conductive lines. The conductive vias extend through respective dielectric layers 132, and the conductive lines extend along respective dielectric layers 132. As an example to form a metallization layer 134, a seed layer (not separately illustrated) is formed over the respective underlying features. For example, the seed layer may be formed on a respective dielectric layer 132 and in any openings through the respective dielectric layer 132. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 134. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 134 of the front-side redistribution structure 130.

The front-side redistribution structure 130 is illustrated as an example. More or fewer dielectric layers 132 and metallization layer(s) 134 than illustrated may be formed by performing the previously described steps any desired quantity of times.

Other variations of the front-side redistribution structure 130 are contemplated. For example, some of the dielectric layers 132 may be formed of an encapsulant, such as a molding compound, epoxy, or the like. A metallization layer 134 may be formed by plating a conductive via from a conductive line. A dielectric layer 132 may be formed by encapsulating that metallization layer 134. Any desired stack of materials may be used for the dielectric layers 132.

Under-bump metallizations (UBMs) 136 may be formed through the upper dielectric layer 132 of the front-side redistribution structure 130. The UBMs 136 are physically and electrically coupled to the upper metallization layer 134 of the front-side redistribution structure 130. The UBMs 136 each include conductive vias and conductive bumps. The conductive vias extend through the upper dielectric layer 132, and the conductive bumps extend along the upper dielectric layer 132. The UBMs 136 may be formed of the same material(s) as the metallization layer(s) 134. In some embodiments, the UBMs 136 have a different size than the metallization layer(s) 134.

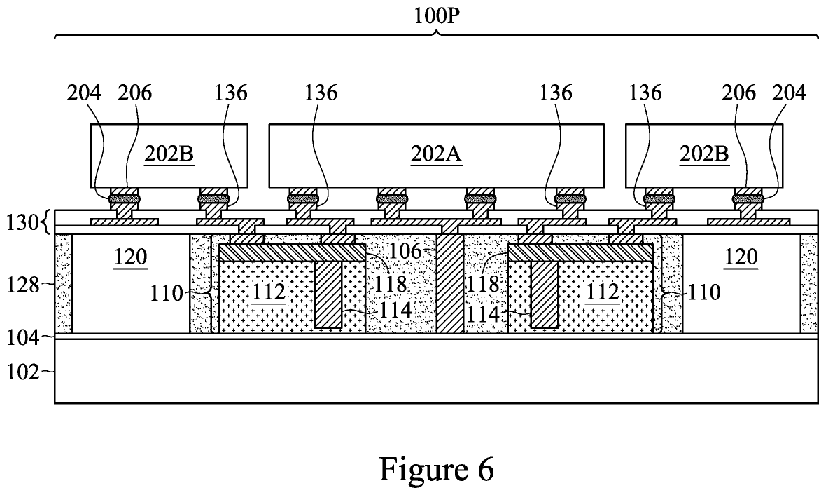

In FIG. 6, integrated circuit devices 202 are attached to the front-side redistribution structure 130. Multiple integrated circuit devices 202 are placed adjacent one another in the package region 100P. The integrated circuit devices 202 in each package region 100P may include logic devices 202A and memory devices 202B. Although the illustrated cross-section shows a single logic device 202A, it should be appreciated that multiple logic devices 202A may be attached. The logic devices 202A and the memory devices 202B may be formed in processes of a same technology node, or may be formed in processes of different technology nodes. For example, the logic devices 202A may be formed by a more advanced process node than the memory devices 202B.

Each logic device 202A may be a central processing unit (CPU), graphics processing unit (GPU), system-on-a-chip (SoC), microcontroller, or the like. The logic devices 202A may be integrated circuit dies (similar to the integrated circuit die 50 described for FIG. 1) or may be die stacks (similar to the die stack 60A described for FIG. 2A). In some embodiments, the logic devices 202A are integrated circuit dies such as system-on-a-chip (SoC) dies. In some embodiments, the logic devices 202A are die stacks such as system-on-integrated-chip (SoIC) devices.

Each memory device 202B may be a dynamic random access memory (DRAM) die, static random access memory (SRAM) die, hybrid memory cube (HMC) module, a high bandwidth memory (HBM) module, or the like. The memory devices 202B may be integrated circuit dies (similar to the integrated circuit die 50 described for FIG. 1) or may be die stacks (similar to the die stack 60B described for FIG. 2B). In some embodiments, the memory devices 202B are die stacks, such as high bandwidth memory (HBM) devices.

In the illustrated embodiment, the integrated circuit devices 202 are attached to the front-side redistribution structure 130 with solder bonds, such as with conductive connectors 204. The conductive connectors 204 may be formed of a conductive material that is reflowable, such as solder, copper, aluminum, gold, nickel, silver, palladium, tin, the like, or a combination thereof. In some embodiments, the conductive connectors 204 are formed by initially forming a layer of solder through methods such as evaporation, electroplating, printing, solder transfer, ball placement, or the like. Once a layer of solder has been formed on the structure, a reflow may be performed in order to shape the conductive connectors 204 into desired bump shapes. Attaching the integrated circuit devices 202 to the front-side redistribution structure 130 may include placing the integrated circuit devices 202 on the front-side redistribution structure 130 and reflowing the conductive connectors 204. The integrated circuit devices 202 may be placed on the front-side redistribution structure 130 using, e.g., a pick-and-place tool. The conductive connectors 204 are reflowed to attach die connectors 206 at the front-sides of the integrated circuit devices 202 to the UBMs 136 of the front-side redistribution structure 130, thereby electrically connecting the front-side redistribution structure 130 to the integrated circuit devices 202. In another embodiment, the integrated circuit devices 202 are attached to the front-side redistribution structure 130 with direct bonds, using the die connectors 206.

The memory devices 202B are disposed directly over the thermal reservoir dies 120. As subsequently described in greater detail, the memory devices 202B overlap the thermal reservoir dies 120 in a plan view. The thermal reservoir dies 120 are in the encapsulant 128. Thus, the thermal reservoir dies 120 will be embedded in the resulting interposers. The thermal reservoir dies 120 occupy space in the interposers that may otherwise be unoccupied (e.g., the space in the encapsulant 128 directly beneath the memory devices 202B). As a result, heat sinks may be incorporated in the integrated circuit package 200 without increasing the package size or increasing manufacturing complexity beyond placement of the thermal reservoir dies 120. During operation, heat may be dissipated from the interconnection dies 110 to the thermal reservoir dies 120. The operating temperature of the interconnection dies 110 may thus be decreased, which may reduce the buildup of hotspots in the integrated circuit package 200, which may improve the performance of the integrated circuit package 200 (especially when the interconnection dies 110 include active devices).

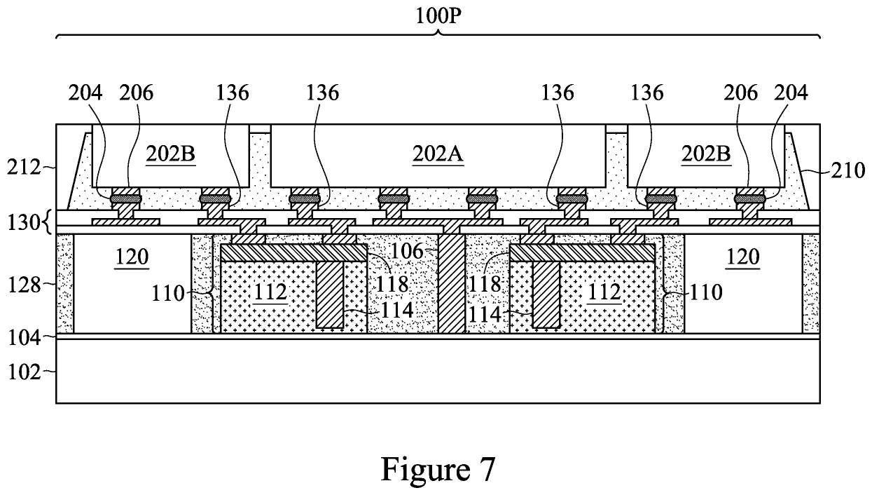

In FIG. 7, an underfill 210 is formed around the conductive connectors 204, and between the front-side redistribution structure 130 and the integrated circuit devices 202. The underfill 210 may reduce stress and protect the joints resulting from the reflowing of the conductive connectors 204. The underfill 210 may be formed of an underfill material such as a molding compound, epoxy, or the like. The underfill 210 may be formed by a capillary flow process after the integrated circuit devices 202 are attached to the front-side redistribution structure 130, or may be formed by a suitable deposition method before the integrated circuit devices 202 are attached to the front-side redistribution structure 130. The underfill 210 may be applied in liquid or semi-liquid form and then subsequently cured.

An encapsulant 212 is formed around the various components. After formation, the encapsulant 212 laterally encapsulates the underfill 210 (if present) and the integrated circuit devices 202. The encapsulant 212 may be a molding compound, epoxy, or the like. The encapsulant 212 may be applied by compression molding, transfer molding, or the like, and may be formed over the front-side redistribution structure 130 such that the integrated circuit devices 202 are buried or covered. The encapsulant 212 is further formed in gap regions between the underfill 210 (if present) and/or the integrated circuit devices 202. The encapsulant 212 may be applied in liquid or semi-liquid form and then subsequently cured.

A removal process may optionally be performed on the encapsulant 212 to expose the integrated circuit devices 202. The removal process may include, for example, a planarization process such as a chemical-mechanical polish (CMP), a grinding process, or the like. The top surfaces of the encapsulant 212 and the integrated circuit devices 202 may be substantially coplanar (within process variations) after the planarization process. The planarization may be omitted, for example, if the integrated circuit devices 202 are already exposed.

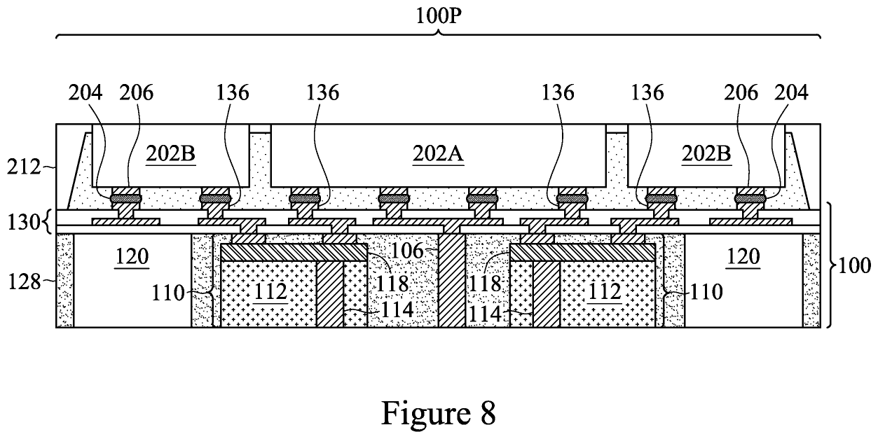

In FIG. 8, a carrier substrate de-bonding is performed to detach (or “de-bond”) the carrier substrate 102 from the interposer wafer 100. In accordance with some embodiments, the de-bonding includes projecting a light such as a laser light or an UV light on the release layer 104 so that the release layer 104 decomposes under the heat of the light and the carrier substrate 102 can be removed. The interposer wafer 100 is then flipped over to prepare for processing of the back-side of the interposer wafer 100. The interposer wafer 100 may be placed on a tape, a carrier substrate, or another suitable support structure (not separately illustrated) for subsequent processing.

A removal process may optionally be performed on the substrates 112 and the encapsulant 128 to expose the through vias 106 and the TSVs 114. The removal process may remove material of the encapsulant 128, the thermal reservoir dies 120, the interconnection dies 110 (e.g., the substrates 112 and the TSVs 114), and/or the through vias 106 until the TSVs 114 and the through vias 106 are exposed. The removal process may include, for example, a planarization process such as a chemical-mechanical polish (CMP), a grinding process, or the like. The back-side surfaces of the encapsulant 128, the thermal reservoir dies 120, the interconnection dies 110 (e.g., the substrates 112 and the TSVs 114), and the through vias 106 may be substantially coplanar (within process variations) after the planarization process.

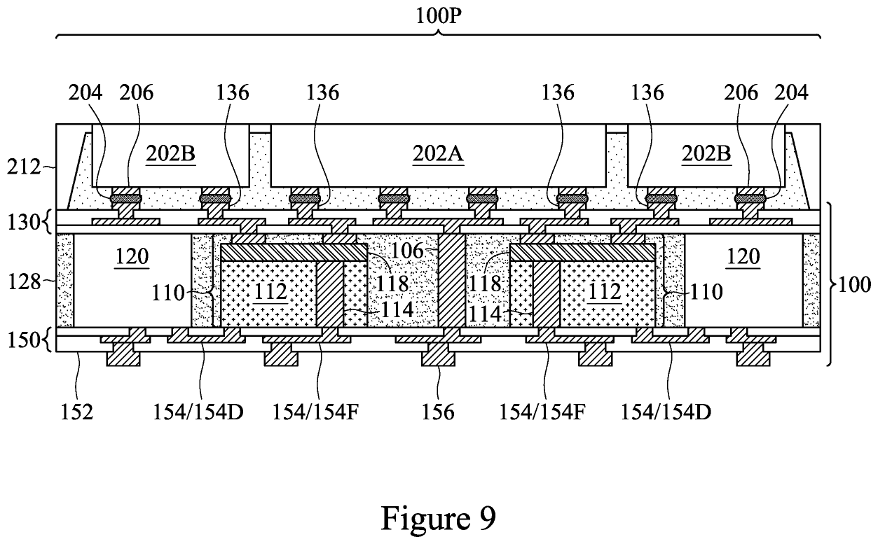

In FIG. 9, a back-side redistribution structure 150 is formed on the back-side surfaces of the encapsulant 128, the thermal reservoir dies 120, the interconnection dies 110 (e.g., the substrates 112 and the TSVs 114), and the through vias 106. The back-side redistribution structure 150 includes dielectric layers 152 and metallization layer(s) 154 (sometimes referred to as redistribution layers or redistribution lines) among the dielectric layers 152. Thus, the back-side redistribution structure 150 includes metallization layer(s) 154 separated from each other by respective dielectric layers 152. The metallization layer(s) 154 of the back-side redistribution structure 150 are connected to the through vias 106 and to the interconnection dies 110 (e.g., the TSVs 114).

In some embodiments, the dielectric layers 152 are formed of a polymer, which may be a photosensitive material such as PBO, polyimide, a BCB-based polymer, or the like, that may be patterned using a lithography mask. In other embodiments, the dielectric layers 152 are formed of a nitride such as silicon nitride, an oxide such as silicon oxide, or the like. The dielectric layers 152 may be formed by spin coating, lamination, CVD, the like, or a combination thereof. After a dielectric layer 152 is formed, it may be patterned to expose underlying conductive features, such as portions of the through vias 106, the TSVs 114, and/or the metallization layer(s) 154. The patterning may be by any acceptable process, such as by exposing the dielectrics layers to light when they are formed of photosensitive material, or by etching using, for example, an anisotropic etch. If the dielectric layers 152 are formed of a photosensitive material, the dielectric layers 152 may be developed after the exposure.

The metallization layer(s) 154 each include conductive vias and/or conductive lines. The conductive vias extend through respective dielectric layers 152, and the conductive lines extend along respective dielectric layers 152. As an example to form a metallization layer 154, a seed layer (not separately illustrated) is formed over the respective underlying features. For example, the seed layer may be formed on a respective dielectric layer 152 and in any openings through the respective dielectric layer 152. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 154. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 154 of the back-side redistribution structure 150.

At least some of the metallization layer(s) 154 (e.g., the lower metallization layer 154) include functional redistribution lines 154F and dummy metal sheets 154D. The functional redistribution lines 154F are electrically functional, and may be electrically coupled to the interconnection dies 110 and the through vias 106. The dummy metal sheets 154D are electrically nonfunctional, and may be electrically isolated from the interconnection dies 110 (e.g., the TSVs 114) and the through vias 106. As subsequently described in greater detail, each dummy metal sheet 154D may have a pattern of openings (through which portions of a dielectric layer 152 extend). A dummy metal sheet 154D extends from under an interconnection die 110 to under a thermal reservoir dies 120 that is adjacent to the interconnection die 110. Optionally, a dummy metal sheet 154D may include conductive vias that extend through an underlying dielectric layer 152 to contact an interconnection die 110 (e.g., a substrate 112) and a thermal reservoir die 120. The dummy metal sheets 154D have a high thermal conductivity, and may help dissipate heat from the interconnection dies 110 to the thermal reservoir dies 120 during operation. The operating temperature of the interconnection dies 110 may thus be decreased, which may improve the performance of the integrated circuit package 200 (especially when the interconnection dies 110 include active devices).

The back-side redistribution structure 150 is illustrated as an example. More or fewer dielectric layers 152 and metallization layer(s) 154 than illustrated may be formed by performing the previously described steps any desired quantity of times.

Other variations of the back-side redistribution structure 150 are contemplated. For example, some of the dielectric layers 152 may be formed of an encapsulant, such as a molding compound, epoxy, or the like. A metallization layer 154 may be formed by plating a conductive via from a conductive line. A dielectric layer 152 may be formed by encapsulating such a metallization layer 154. Any desired stack of materials may be used for the dielectric layers 152.

UBMs 156 may be formed through the lower dielectric layer 152 of the back-side redistribution structure 150. The UBMs 156 are physically and electrically coupled to the lower metallization layer 154 of the back-side redistribution structure 150. The UBMs 156 each include conductive vias and conductive bumps. The conductive vias extend through the lower dielectric layer 152, and the conductive bumps extend along the lower dielectric layer 152. The UBMs 156 may be formed of the same material(s) as the metallization layer(s) 154. In some embodiments, the UBMs 156 have a different size than the metallization layer(s) 154.

The thermal reservoir dies 120 are between the front-side redistribution structure 130 and the back-side redistribution structure 150. Thus, the thermal reservoir dies 120 will be embedded in the resulting interposers. The thermal reservoir dies 120 are electrically nonfunctional, and may be electrically isolated from the metallization layer of the front-side redistribution structure 130 and the back-side redistribution structure 150.

In FIG. 10, a package substrate 220 is attached to the interposer wafer 100 (e.g., to the back-side redistribution structure 150). The package substrate 220 includes a substrate core 222, which may be formed of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 222 may be a SOI substrate. Generally, an SOI substrate includes a layer of a semiconductor material such as a layer of silicon, germanium, silicon germanium, or combinations thereof. In some embodiments, the substrate core 222 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 222.

The substrate core 222 may include passive devices and/or active devices (not separately illustrated). Devices such as transistors, capacitors, resistors, combinations thereof, and the like may be used to generate the structural and functional requirements of the design for the system. The devices may be formed using any suitable methods. In some embodiments, the substrate core 222 is substantially free of active devices and passive devices.

The substrate core 222 may also include metallization layers (not separately illustrated). The package substrate 220 further includes bond pads 224 over the metallization layers of the substrate core 222. The metallization layers may be formed over the passive devices and/or active devices and are designed to connect the various devices to form functional circuitry. The metallization layers may be formed of alternating layers of dielectric material (e.g., low-k dielectric material) and conductive material (e.g., copper), with vias interconnecting the layers of conductive material, and may be formed through any suitable process (such as deposition, damascene, or the like).

The package substrate 220 may be attached to the back-side redistribution structure 150 with solder bonds, such as with conductive connectors 226. The conductive connectors 226 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 226 may include a conductive material such as solder, copper, aluminum, gold, nickel, silver, palladium, tin, the like, or a combination thereof. In some embodiments, the conductive connectors 226 are formed by initially forming a layer of solder through evaporation, electroplating, printing, solder transfer, ball placement, or the like. Once a layer of solder has been formed on the structure, a reflow may be performed in order to shape the solder into the desired bump shapes of the conductive connectors 226. Attaching the package substrate 220 to the back-side redistribution structure 150 may include placing the package substrate 220 on the and back-side redistribution structure 150 reflowing the conductive connectors 226. The package substrate 220 may be placed on the back-side redistribution structure 150 using, e.g., a pick-and-place tool. The conductive connectors 226 are reflowed to attach the bond pads 224 to the UBMs 156 of the back-side redistribution structure 150. The conductive connectors 226 connect the interposer wafer 100, including metallization layers of the back-side redistribution structure 150, to the package substrate 220, including metallization layers of the substrate core 222. Thus, the package substrate 220 are electrically connected to the integrated circuit devices 202 in the package region 100P.

Additionally, passive devices (not separately illustrated) may be attached to the interposer wafer 100 and/or the package substrate 220. For example, the passive devices may be attached to the interposer wafer 100, such as to the same surface of the back-side redistribution structure 150 as the conductive connectors 226. Additionally or alternatively, the passive devices may be attached to the package substrate 220, such as to the same surface of the package substrate 220 as the conductive connectors 226. The passive devices may include capacitors, resistors, inductors, the like, or a combination thereof. The passive devices may be surface mount devices (SMDs), 2-terminal integrated passive devices (IPDs), multi-terminal IPDs, or the like.

In some embodiments, an encapsulant 232 is formed around the various components. After formation, the encapsulant 232 laterally encapsulates the passive devices (if present), the conductive connectors 226, and the package substrate 220. The encapsulant 232 may be formed between the package substrate 220 and the back-side redistribution structure 150. The encapsulant 232 may be a molding compound, epoxy, or the like. The encapsulant 232 may be applied by compression molding, transfer molding, or the like. The encapsulant 232 may be applied in liquid or semi-liquid form and then subsequently cured.

Additionally, a singulation process is performed by cutting along scribe line region between the package region 100P and adjacent package regions (not separately illustrated). The singulation process may include sawing, dicing, or the like. The singulation process singulates the package regions from one another. The resulting, singulated integrated circuit package 200 is from the package region 100P. The singulation process forms an interposer 240 from the singulated portion of the interposer wafer 100. As a result of the singulation process, the outer sidewalls of the interposer 240, the encapsulant 212, and the encapsulant 232 are laterally coterminous (within process variations).

FIG. 11 is a plan view of the integrated circuit package 200, showing a layout of the interconnection dies 110, the thermal reservoir dies 120, and the integrated circuit devices 202. FIG. 10 is shown along reference cross-section A-A′ of FIG. 11. The integrated circuit devices 202 are shown with solid lines, while the underlying components (e.g., the interconnection dies 110 and the thermal reservoir dies 120) are shown with dashed lines.

The logic devices 202A may be larger than the memory devices 202B. The integrated circuit devices 202 may have a symmetric layout or an asymmetric layout in the plan view. In this example, the integrated circuit devices 202 have a symmetric layout in which the memory devices 202B are arranged along opposing sides of the logic devices 202A.

The interconnection dies 110 will be utilized for direct communication between the logic devices 202A and the memory devices 202B. The interconnection dies 110 are located in regions that are disposed between the integrated circuit devices 202 so that each interconnection die 110 is disposed beneath multiple integrated circuit devices 202. In this example, each interconnection die 110 is either overlapped by a logic device 202A and multiple memory devices 202B in the plan view or is overlapped by multiple logic devices 202A in the plan view.

The thermal reservoir dies 120 may be electrically isolated from the integrated circuit devices 202. The thermal reservoir dies 120 are located in regions that would otherwise be unoccupied, specifically, the space directly beneath the memory devices 202B. The thermal reservoir dies 120 may not be disposed directly beneath the logic devices 202A. In this example, each thermal reservoir die 120 is overlapped by a corresponding memory device 202B in the plan view. A thermal reservoir die 120 may be confined within the edges of the overlying memory device 202B in the plan view (as shown in FIG. 11). A thermal reservoir die 120 may not be confined within the edges of the overlying memory device 202B (as shown in FIG. 10).

FIG. 12 is a plan view of the integrated circuit package 200, showing a portion of the back-side redistribution structure 150—specifically a region 100R from FIG. 10. Features of a metallization layer 154 (including a functional redistribution line 154F and multiple dummy metal sheets 154D) are shown with solid lines, while the overlying components (e.g., an interconnection die 110 and a thermal reservoir die 120) are shown with dashed lines.

The dummy metal sheets 154D are part of a dummy metal pattern overlapped by the interconnection die 110 and the thermal reservoir die 120 in the plan view. Each dummy metal sheet 154D is overlapped by at least one interconnection die 110 and at least one thermal reservoir die 120 in the plan view. Each dummy metal sheet 154D may extend from under an interconnection die 110 to under a thermal reservoir die 120. Each dummy metal sheet 154D may include a single, continuous layer of a metal. Each dummy metal sheet 154D has a pattern of openings 158. The pattern of the openings 158 may be a regular pattern or an irregular pattern. The openings 158 are shown as being square openings, but they may be round openings, slotted openings, or the like. A first subset of the openings 158 of a dummy metal sheet 154D are disposed beneath the interconnection die 110 while a second subset of the openings 158 of the dummy metal sheet 154D are disposed beneath the thermal reservoir die 120. The openings 158 may each be the same size, having the same width and the same length. The width of the openings 158 may be substantially equal to the length of the openings 158. In some embodiments, the width of the openings 158 is in the range of 10 μm to 30 μm, and the length of the openings 158 is in the range of 10 μm to 30 μm. The openings 158 may be sized to accommodate degassing during thermal expansion under high heat, which may improve the reliability of the integrated circuit package 200.

A functional redistribution line 154F may be overlapped by an interconnection die 110 and a thermal reservoir die 120 in the plan view. A functional redistribution line 154F may be disposed between two of the dummy metal sheets 154D in the plan view.

FIGS. 13-14B are views of an integrated circuit package, in accordance with some other embodiments. FIG. 13 is a cross-sectional view while FIGS. 14A-14B are plan views. This embodiment is similar to the embodiment of FIG. 10, except the thermal reservoir dies 120 include metal features 122 in their substrates, which may help further increase the amount of heat dissipated from the interconnection dies 110. The metal features 122 may extend from the front-side surfaces of the thermal reservoir dies 120 to the back-side surfaces of the thermal reservoir dies 120. The metal features 122 may be formed in the substrates of the thermal reservoir dies 120 (e.g., by acceptable etching and plating techniques) before the thermal reservoir dies 120 are packaged. The metal features 122 may be through-substrate vias (TSVs), such as through-silicon vias or the like. The metal features 122 are electrically nonfunctional, and may be electrically isolated from the metallization layer of the front-side redistribution structure 130 and the back-side redistribution structure 150. Optionally, when a dummy metal sheet 154D includes conductive vias, the conductive vias may extend through an underlying dielectric layer 152 to contact an interconnection die 110 (e.g., a substrate 112) and a metal feature 122 of a thermal reservoir die 120.

FIGS. 14A-14B are plan views of a thermal reservoir die 120, showing a layout of the metal features 122. The metal features 122 may be metal pillars, as shown by FIG. 14A. The metal features 122 may be metal plates, as shown by FIG. 14B. Other types of metal features 122 could also be utilized.

FIG. 15 is a cross-sectional view of an integrated circuit package 200, in accordance with some other embodiments. This embodiment is similar to the embodiment of FIG. 10, except a thermal interface material 124 is formed between adjacent pairs of the thermal reservoir dies 120 and the interconnection dies 110. The thermal interface material 124 may be a metal paste (e.g., silver paste, indium solder paste, etc.) a polymeric material (e.g., molding compound, which may (or may not) have a high k-value), or the like, which may be formed by dispensing, printing, or the like. In this embodiment, the thermal interface material 124 is different than the encapsulant 128.

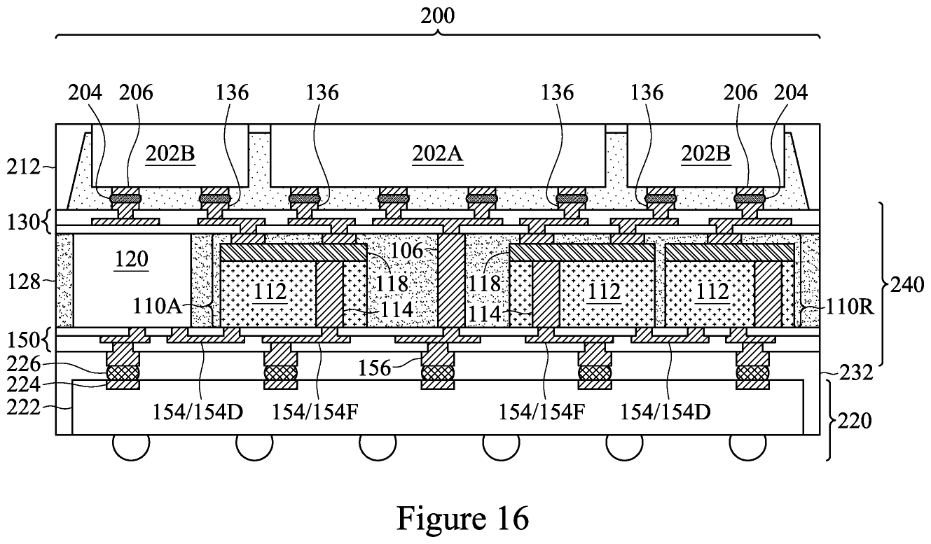

FIG. 16 is a cross-sectional view of an integrated circuit package 200, in accordance with some other embodiments. This embodiment is similar to the embodiment of FIG. 10, except additional interconnection dies 110R are used in lieu of some of the thermal reservoir dies 120. The additional interconnection dies 110R may be confined within the edges of an overlying memory device 202B in the plan view (similar to the thermal reservoir dies 120). The additional interconnection dies 110R may be substantially free of active devices, and thus may consume a low amount of power and generate a low amount of heat during operation. Such interconnection dies 110R may also be able to function as heat sinks to draw heat away from interconnection dies 110A with active devices during operation. The substrates 112 of the interconnection dies 110R may be larger (in the plan view) than the substrates 112 of the interconnection dies 110A. Optionally, a dummy metal sheet 154D may include conductive vias that extend through an underlying dielectric layer 152 to contact an interconnection die 110A (e.g., a substrate 112) and an interconnection die 110R (e.g., a substrate 112).

Embodiments may achieve advantages. The thermal reservoir dies 120 are heat sinks that draw heat away from the interconnection dies 110 during operation. Specifically, during operation, heat may be dissipated from the interconnection dies 110 to the thermal reservoir dies 120. Additionally, the dummy metal sheets 154D, having a high thermal conductivity, may help dissipate heat from the interconnection dies 110 to the thermal reservoir dies 120 during operation. The operating temperature of the interconnection dies 110 may thus be decreased, which may improve the performance of the integrated circuit package 200 (especially when the interconnection dies 110 include active devices).

In an embodiment, a device includes: an interposer including: a front-side redistribution structure; a back-side redistribution structure; an encapsulant between the front-side redistribution structure and the back-side redistribution structure; an interconnection die in the encapsulant; and a thermal reservoir die in the encapsulant, the thermal reservoir die adjacent the interconnection die; a memory device attached to the front-side redistribution structure, the memory device overlapping the thermal reservoir die in a plan view; and a logic device attached to the front-side redistribution structure, the logic device and the memory device each overlapping the interconnection die in the plan view. In some embodiments of the device, the thermal reservoir die includes a semiconductor substrate. In some embodiments of the device, the thermal reservoir die includes a metal substrate. In some embodiments of the device, the thermal reservoir die includes: a substrate; and metal features in the substrate. In some embodiments of the device, the thermal reservoir die is confined within edges of the memory device in the plan view. In some embodiments of the device, the interconnection die includes a die bridge that connects the memory device to the logic device. In some embodiments of the device, the back-side redistribution structure includes: a dummy metal pattern, the interconnection die and the thermal reservoir die each overlapping the dummy metal pattern in the plan view. In some embodiments, the device further includes: a package substrate attached to the back-side redistribution structure.

In an embodiment, a device includes: a package substrate; an interposer including: a back-side redistribution structure attached to the package substrate, the back-side redistribution structure including a first dummy metal sheet having first openings; an interconnection die over the back-side redistribution structure; a thermal reservoir die over the back-side redistribution structure, the first dummy metal sheet extending from under the interconnection die to under the thermal reservoir die; an encapsulant around the interconnection die and the thermal reservoir die; and a front-side redistribution structure over the encapsulant; and an integrated circuit device attached to the front-side redistribution structure. In some embodiments of the device, a width of the first openings is substantially equal to a length of the first openings. In some embodiments of the device, each of the first openings has the same width and the same length. In some embodiments of the device, the back-side redistribution structure further includes: a second dummy metal sheet having second openings; and a functional redistribution line between the first dummy metal sheet and the second dummy metal sheet. In some embodiments of the device, the interposer further includes: a thermal interface material between the thermal reservoir die and the interconnection die. In some embodiments of the device, the interconnection die includes active devices. In some embodiments of the device, a surface of the encapsulant is substantially coplanar with a surface of the thermal reservoir die.

In an embodiment, a method includes: encapsulating an interconnection die and a thermal reservoir die with an encapsulant, a front-side surface of the encapsulant being substantially coplanar with a front-side surface of the thermal reservoir die; forming a front-side redistribution structure on the front-side surface of the encapsulant and the front-side surface of the thermal reservoir die, the front-side redistribution structure including first redistribution lines that are connected to the interconnection die; and attaching a logic device and a memory device to the front-side redistribution structure, the memory device overlapping the thermal reservoir die in a plan view. In some embodiments of the method, the thermal reservoir die is confined within edges of the memory device in the plan view. In some embodiments of the method, the logic device and the memory device each overlap the interconnection die in the plan view. In some embodiments, the method further includes: forming a back-side redistribution structure on a back-side surface of the encapsulant and a back-side surface of the thermal reservoir die; and attaching a package substrate to the back-side redistribution structure. In some embodiments of the method, the back-side redistribution structure is formed after the attaching the logic device and the memory device to the front-side redistribution structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
an interposer comprising:
a front-side redistribution structure;
a back-side redistribution structure;
an encapsulant between the front-side redistribution structure and the back-side redistribution structure;
an interconnection die in the encapsulant; and
a thermal reservoir die in the encapsulant, the thermal reservoir die adjacent the interconnection die;
a memory device attached to the front-side redistribution structure, the memory device overlapping the thermal reservoir die in a plan view; and
a logic device attached to the front-side redistribution structure, the logic device and the memory device each overlapping the interconnection die in the plan view.

2. The device of claim 1, wherein the thermal reservoir die comprises a semiconductor substrate.

3. The device of claim 1, wherein the thermal reservoir die comprises a metal substrate.

4. The device of claim 1, wherein the thermal reservoir die comprises:
a substrate; and
metal features in the substrate.

5. The device of claim 1, wherein the thermal reservoir die is confined within edges of the memory device in the plan view.

6. The device of claim 1, wherein the interconnection die comprises a die bridge that connects the memory device to the logic device.

7. The device of claim 1, wherein the back-side redistribution structure comprises:
a dummy metal pattern, the interconnection die and the thermal reservoir die each overlapping the dummy metal pattern in the plan view.

8. The device of claim 1, further comprising:
a package substrate attached to the back-side redistribution structure.

9. A device comprising:
a package substrate;
an interposer comprising:
a back-side redistribution structure attached to the package substrate, the back-side redistribution structure comprising a first dummy metal sheet having first openings;
an interconnection die over the back-side redistribution structure;
a thermal reservoir die over the back-side redistribution structure, the first dummy metal sheet extending from under the interconnection die to under the thermal reservoir die;
an encapsulant around the interconnection die and the thermal reservoir die; and
a front-side redistribution structure over the encapsulant; and
an integrated circuit device attached to the front-side redistribution structure.

10. The device of claim 9, wherein a width of the first openings is substantially equal to a length of the first openings.

11. The device of claim 9, wherein each of the first openings has the same width and the same length.

12. The device of claim 9, wherein the back-side redistribution structure further comprises:
a second dummy metal sheet having second openings; and
a functional redistribution line between the first dummy metal sheet and the second dummy metal sheet.

13. The device of claim 9, wherein the interposer further comprises:
a thermal interface material between the thermal reservoir die and the interconnection die.

14. The device of claim 9, wherein the interconnection die comprises active devices.

15. The device of claim 9, wherein a surface of the encapsulant is substantially coplanar with a surface of the thermal reservoir die.

16. A method comprising:
encapsulating an interconnection die and a thermal reservoir die with an encapsulant, a front-side surface of the encapsulant being substantially coplanar with a front-side surface of the thermal reservoir die;
forming a front-side redistribution structure on the front-side surface of the encapsulant and the front-side surface of the thermal reservoir die, the front-side redistribution structure comprising first redistribution lines that are connected to the interconnection die; and
attaching a logic device and a memory device to the front-side redistribution structure, the memory device overlapping the thermal reservoir die in a plan view.

17. The method of claim 16, wherein the thermal reservoir die is confined within edges of the memory device in the plan view.

18. The method of claim 16, wherein the logic device and the memory device each overlap the interconnection die in the plan view.

19. The method of claim 16, further comprising:
forming a back-side redistribution structure on a back-side surface of the encapsulant and a back-side surface of the thermal reservoir die; and
attaching a package substrate to the back-side redistribution structure.

20. The method of claim 19, wherein the back-side redistribution structure is formed after the attaching the logic device and the memory device to the front-side redistribution structure.
